(19) United States
(12) Patent Application Publication
(10) Pub. No.: US 2011/0079908 A1
(43) Pub. Date: Apr. 7, 2011

(54) Stress buffer to protect device features

(75) Inventors: Siong Cho Lau, Perak (MY); May Nee Lim, Perak (MY); Soi Yoke See Thoh, Perak (MY); Wai Nam Leong, Perak (MY)

(73) Assignee: Unisem Advanced Technologies Sdn. Bhd., Kuala Lumpur (MY)

(21) Appl. No.: 12/924,445

(22) Filed: Sep. 28, 2010

Related U.S. Application Data
(60) Provisional application No. 61/248,912, filed on Oct. 6, 2009.

(51) Int. Cl. H01L 23/00; H01L 21/3205

(52) U.S. Cl. 257/761; 438/763; 257/E21.295; 257/E23.194

(57) ABSTRACT

Disclosed is a stress buffer structure intended to be disposed adjacent a face of a semiconductor substrate. The stress buffer structure includes at least one polymer layer formed on the face of the semiconductor substrate and a plurality of metal plates disposed over the polymer layer, wherein the metal plates is physically and electrically isolated from the bond pads of the semiconductor substrate. The disclosed stress buffer structure provides protection to semiconductor components that are sensitive to stress. Also disclosed are semiconductor packages having the disclosed stress buffer structure and the methods of making the semiconductor packages.

### CROSS REFERENCE TO RELATED APPLICATIONS

This Application claims the benefit of U.S. provisional Patent Application Ser. No. 61/248,912, filed on Oct. 6, 2009, the disclosure of which is incorporated herein by reference in its entirety.

### BACKGROUND

1. Field

This disclosure relates generally to semiconductor devices and the methods of formation, and more particularly to stress buffer structures effective to spread or distribute stress imposed on delicate device features, thus protecting these features from fracture and/or damage.

2. Background

Semiconductor devices typically include various device features. Some of these features may be delicate in nature and are susceptible to fracture and damage when they are exposed to internal and external stresses. More often, the localized damage to the device features lead to catastrophic failure of the semiconductor devices. Accordingly, the integrity of the semiconductor devices may be greatly compromised if the device features are not sufficiently protected from various stresses that develop during the manufacture, handling and use of the semiconductor devices.

Conventional semiconductor packages offer very little or no additional protection to sensitive device features. FIG. 1 is a cross-sectional view of a conventional semiconductor package. The package structure includes a plurality of bond pads 3 and a passivation layer 1, both formed on face 9 (i.e. the epitaxial layer) of substrate 10. The package also includes one or more device features 2 under the passivation layer 1.

Passivation layer 1 is normally formed of an electrically non-conductive material such as silicon dioxide or silicon nitride. The passivation layer serves the function of electrical isolation. It can also keep out dust and moisture, thus protecting the device features from corrosion. However, passivation layer 1 normally is not effective in protecting device feature 2 from sustaining damages resulted from internal and external stresses.

To obtain better protection to device features and to reduce cost, some manufacturers replace passivation layer 1 with a polymer coating 8 as illustrated in FIG. 2. Polymer coating 8 is normally made of an organic material such as polyimide or benzocyclobutene (BCB). This organic material is compliant, accordingly, polymer coating 8 may serve as a stress buffer layer to protect device feature 2. However, in certain circumstances, the polymer coating is still insufficient to provide the needed protection to the device features, especially the delicate ones positioned directly under the surface of the semiconductor substrate.

Accordingly, there is still a need for a stress buffer structure that is effective to spread or distribute the stress imposed on the semiconductor device features, thus protecting these features from damage, which in turn, improves the integrity of the semiconductor devices.

### BRIEF SUMMARY

In one aspect, the present disclosure provides a stress buffer structure intended to be disposed adjacent a face of a semiconductor substrate. The structure includes a first polymer layer having at least a first side contacting at least part of a passivation layer formed on the semiconductor substrate, the semiconductor substrate having one or more bond pads on the same face; a second polymer layer having a first side that contacts an opposing second side of the first polymer layer; a metal plate contacting an opposing second side of the second polymer layer, wherein the metal plate has one or more metal layers and is physically and electrically isolated from the bond pads of the semiconductor substrate.

The metal plate of the disclosure includes a first metal layer disposed over the second side of the second polymer layer. Optionally, the metal plate includes a second metal layer disposed over the first metal layer, and optionally a third metal layer disposed over the second metal layer.

In another aspect, the present disclosure provides a stress buffer structure intended to be disposed over a polymer coating formed on a face of a semiconductor substrate. Along with the polymer coating, the semiconductor substrate has one or more bond pads on the same face of the substrate. The stress buffer structure of this embodiment includes a first polymer layer having at least a first side contacting at least part of the polymer coating; and a metal plate contacting an opposing second side of the first polymer layer, wherein the metal plate has one or more metal layers and is physically and electrically isolated from the bond pads of the semiconductor substrate.

The disclosed stress buffer structures have a stress improvement on the semiconductor package because they spread and distribute the stress imposed on the delicate device features of the semiconductor substrate, thus protecting these features from damage during handling and use.

The present disclosure also provides semiconductor package having the disclosed stress buffer structure and the methods of making the same.

### BRIEF DESCRIPTION OF THE DRAWINGS

FIG. 1 illustrates a cross-sectional view of an isolated portion of a semiconductor package according to a first embodiment of the prior art.

FIG. 2 illustrates a cross-sectional view of an isolated portion of a semiconductor package according to a second embodiment of the prior art.

FIGS. 3a-3f illustrate cross-sectional views of isolated portions of semiconductor packages according to some embodiments of the present disclosure, showing stress buffer structures formed on the passivation layers of the semiconductor substrates.

FIGS. 4a-4d illustrate cross-sectional views of isolated portions of semiconductor packages according to some embodiments of the present disclosure, showing stress buffer structures, which include a polymer protection layer on the metal plate, formed on the passivation layers of the semiconductor substrates.

FIGS. 5a-5c illustrate cross-sectional views of isolated portions of semiconductor packages according to some embodiments of the present disclosure, showing stress buffer structures formed on the polymer coatings of the semiconductor substrates.

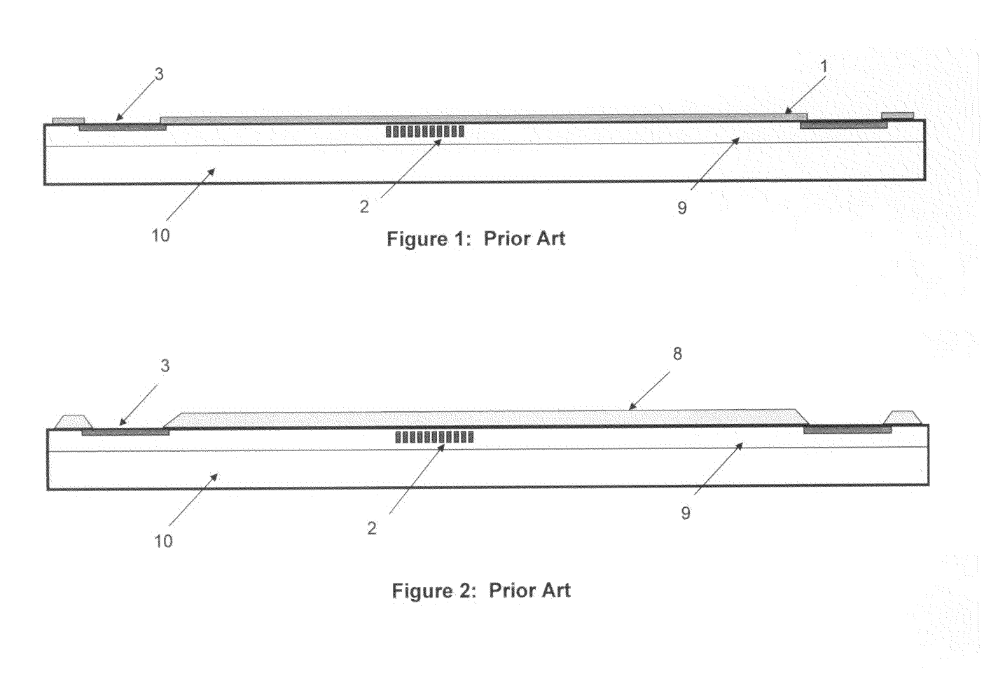

### DETAILED DESCRIPTION

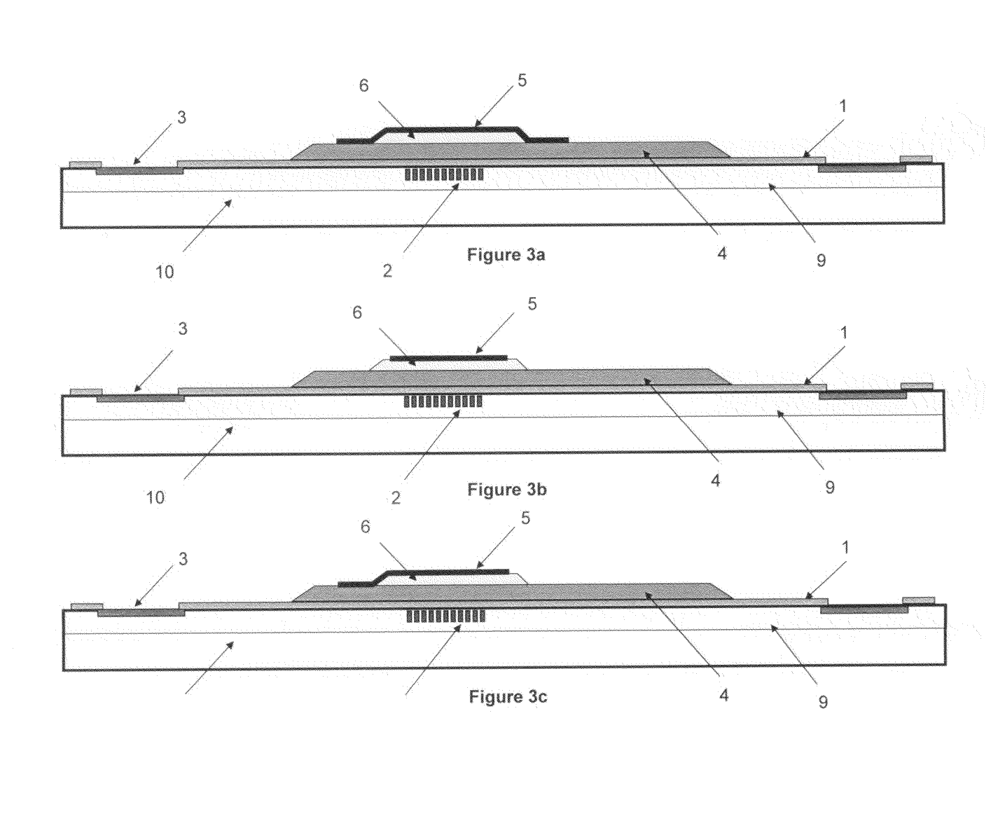

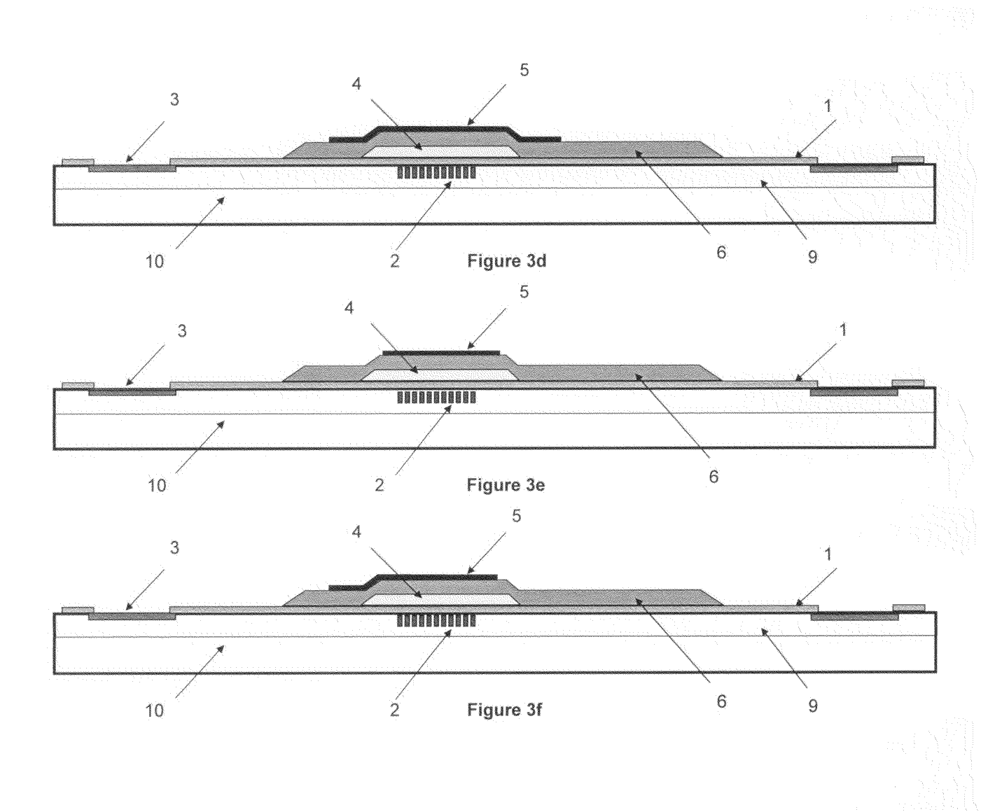

FIGS. 3a-3f illustrate cross-sectional views of isolated portions of semiconductor structures formed on substrate 10 according to a first embodiment of the disclosure. As shown in these figures, on surface 9 of substrate 10, there are a plurality of bond pads 3. Bond pads 3 can be formed via any conventional means. It is made of a conductive material. Most commonly used is Al or Cu.

Formed on face 9 of substrate 10, is a passivation layer 1. Passivation layer 1 in FIGS. 3a-3f is normally formed of an electrically non-conductive material such as silicon dioxide or silicon nitride.

On passivation layer 1, there are a plurality of apertures to expose at least a portion of each bond pad 3. The apertures can be of any shape and size.

Underneath passivation layer 1, there are one or more device features 2. In one embodiment, device feature 2 is delicate and sensitive to stress. Typically, device feature 2, when exposed to stress, may cause a shift in device voltage, current or frequency response, leading to device functional failures.

To protect device feature 2, a stress buffer structure of the disclosure is disposed adjacent face 9 of semiconductor substrate 10. The stress buffer structure includes a first polymer layer 4 having at least a first side contacting at least part of passivation layer 1, a second polymer layer 6 having a first side that contacts an opposing second side of first polymer 4, and a metal plate 5 contacting an opposing second side of second polymer layer 6, where metal plate 5 is physically and electrically isolated from bond pads 3.

First polymer layer 4 has at least a first side contacting at least part of passivation layer 1. It can cover a significant portion of, including the entire surface of passivation layer 1 and serves as general protection as illustrated in FIGS. 3a, 3b and 3c. Alternatively, first polymer layer 4 can just cover one or more device features 2 as illustrated in FIGS. 3d, 3e and 3f.

First polymer layer 4 can be polyimide, benzocyclobutene, benzocyclobutene-based polymers, polybenzoxazole, or any compliant dielectric materials known to a person skilled in the field. First polymer layer 4 has a thickness ranging from about 1 to about 50 microns in single or multiple coatings.

Second polymer layer 6 has a first side that contacts an opposing second side of first polymer 4. In one embodiment, second polymer layer 6 is deposited over and in contact with only the portion of the second side of first polymer 4 that covers device feature 2. This embodiment is illustrated by FIGS. 3a, 3b and 3c. In another embodiment, second polymer layer 6 overlays first polymer layer 4 and extends onto a portion of passivation layer 1 as illustrated by FIGS. 3d, 3e and 3f.

Second polymer layer 6 can be polyimide, benzocyclobutene, benzocyclobutene-based polymers, polybenzoxazole or any compliant dielectric materials known to a person skilled in the field. It has a thickness ranging from 1 to about 50 microns in single or multiple coatings. First polymer layer 4 and second polymer layer 6 can be made of same or different materials. When they are of different materials, it is preferred that the materials are selected in such a way that first polymer layer 4 adheres well to second polymer layer 6.

Metal plate 5 of the disclosure is physically and electrically isolated from bond pads 3 of semiconductor substrate 10. It is disposed over and in contact with an opposing second side of second polymer layer 6. In one embodiment, metal plate 5 is disposed over only a portion of the second side of second polymer 6. As illustrated in FIGS. 3b and 3e, metal plate 5 can be deposited in a way that covers only device feature 2. In another embodiment, metal plate 5 overlays at least a portion of second polymer layer 6 and extends onto a portion of first polymer layer 4 as shown in FIGS. 3a, 3c, 3d and 3f.

Metal plate 5 of the stress buffer structure includes one or more metal layers. In some embodiments, metal plate 5 includes a first metal layer disposed over the second side of second polymer layer 6. The metal plate may optionally include a second metal layer disposed over the first metal layer, and optionally a third metal layer disposed over the second metal layer.

The first metal layer is usually Ti, TiW, V, or other metals or metal alloys which have a good adhesion property to second polymer layer 6 and/or first polymer layer 4. The thickness of the first metal layer can range from about 0.02 to about 20 microns. Besides functioning as an adhesion layer, the first metal layer, when of sufficient thickness (1 to 20 microns), also facilitates the distribution and spread of the stress imposed on device feature 2.

The second metal layer is optional if the first metal layer is thick enough to function as stress distributor or spreader. The second metal layer can be Cu, Al, Ni, and alloys or mixtures thereof. It has a thickness of from about 0.2 to 20 microns. This metal layer facilitates the distribution and spread of the stress imposed on the device feature 2.

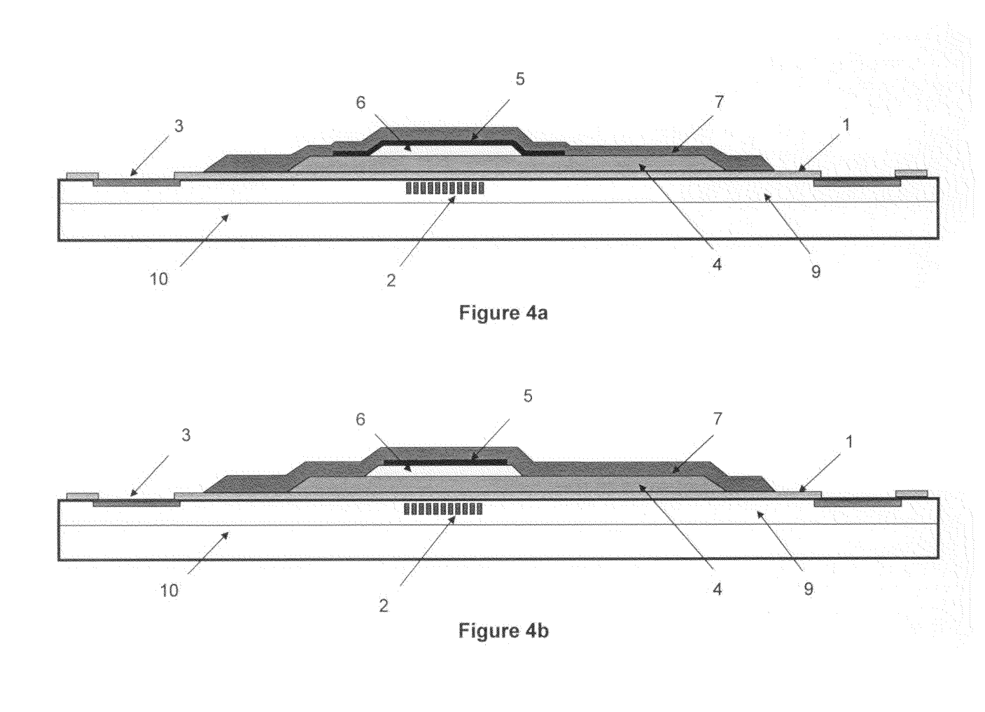

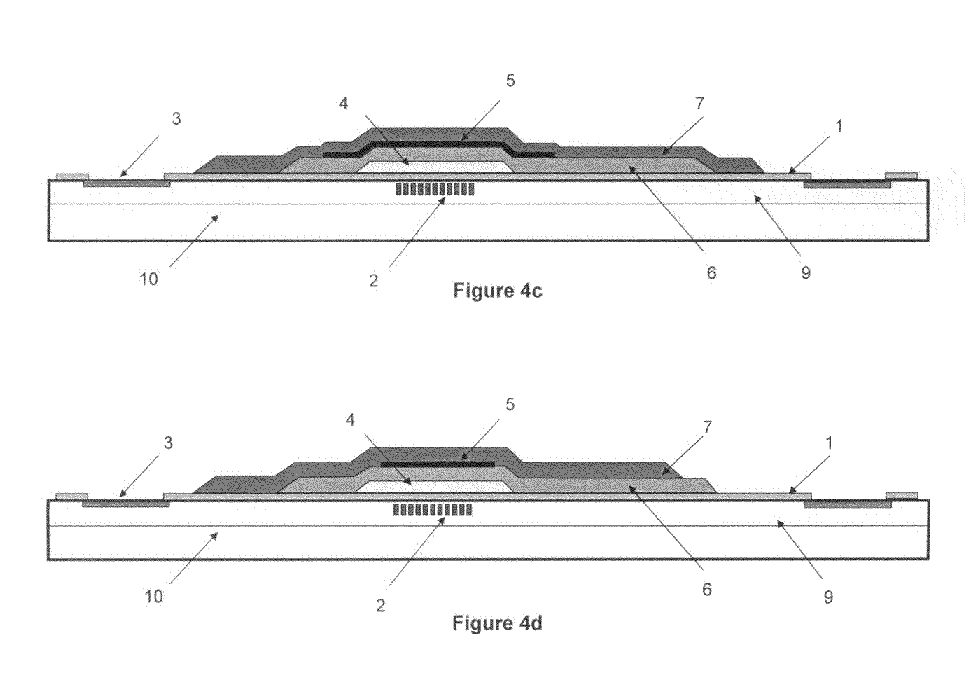

The third metal layer is optional. It may be added if protection of the second metal layer against discoloration or corrosion is necessary, or if there is a need to prepare the surface of metal plate 5 for another polymer layer as illustrated in FIGS. 4a-4d. This third metal layer is one with good adhesion properties and is relatively inert. It can be Ti, TiW, V or other relatively inert materials. The thickness of the third metal layer may range from 0.02 to 2 microns.

The stress buffer structure of the disclosure may optionally include a third polymer layer 7 disposed over metal plate 5 (FIGS. 4a-4d). The coverage area of polymer layer 7 is not particularly limited. In one embodiment as shown in FIG. 4a, polymer layer 7 overlays metal plate 5 and extends onto a portion of first polymer layer 4 and passivation layer 1. In another embodiment as shown in FIG. 4b, third polymer layer 7 overlays metal plate 5 and extends onto at least a portion of second polymer layer 6, first polymer layer 4 and passivation layer 1. In yet another embodiment as show in FIG. 4c, polymer layer 7 overlays metal plate 5 and extends onto at least a portion of second polymer layer 6 and passivation layer 1. In still another embodiment as shown in FIG. 4d, polymer layer 7 overlays metal plate 5 and extends onto at least a portion of second polymer layer 6.

The third polymer layer 7 can be made from inert materials such as polyimide, benzocyclobutene, benzocyclobutene-based polymers, polybenzoxazole or any repassivation materials known to a person skilled in the field. It has a thickness ranging from 1 to about 50 microns in single or multiple coatings.

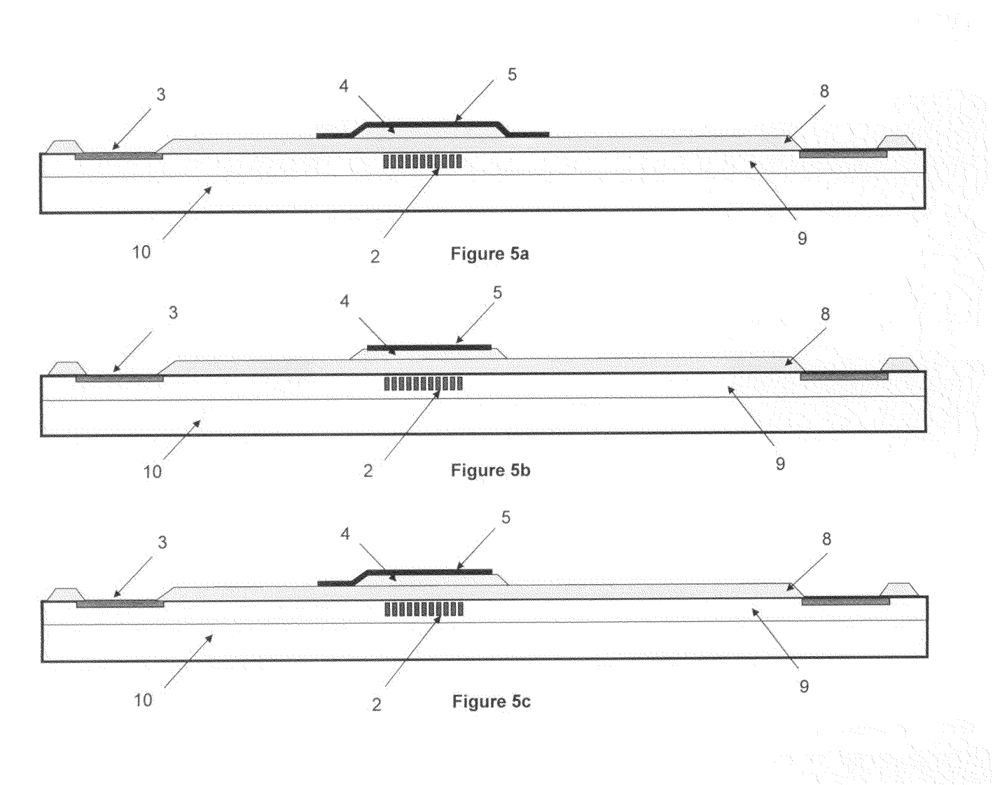

For semiconductor substrates that have a polymer coating formed on a substrate as shown in FIG. 2, a stress buffer structure of the disclosure can be built directly on coating 8 of substrate 10. As shown in FIGS. 5a-5c, the stress buffer structure in this embodiment includes a first polymer layer 4 having at least a first side contacting at least part of polymer coating 8, and a metal plate 5 having a plurality of metal layers contacting an opposing second side of first polymer layer 4, where metal plate 5 has one or more metal layers and is physically and electrically isolated from bond pads 3.

First polymer layer 4 corresponds to first polymer layer 4 as described above in the first embodiment of the stress buffer structures of the disclosure. Metal plate 5 is the same as that described above.

If needed, the stress buffer structure of this embodiment may also include a second polymer layer that protects metal stack 5. This optional second polymer layer corresponds to the third polymer layer 7 described in the first embodiment of the stress buffer structure.

The stress buffer structures of the disclosure can be formed via conventional ways. The deposition method for each polymer layers is not particularly limited. Each layer of the metal plate can be formed using any conventional fabrication techniques, for example, sputtering, evaporation and plating processes.

The disclosed stress buffer structures have a stress improvement on the semiconductor package because they spread and distribute the stress imposed on the delicate device features of the semiconductor substrate, thus protecting these structures from damage during the manufacture, handling and use of the semiconductor package.

What is claimed is:

1. A stress buffer structure intended to be disposed adjacent a face of a semiconductor substrate comprising:
a first polymer layer having at least a first side contacting at least part of a passivation layer formed on said semiconductor substrate, said semiconductor substrate having one or more bond pads on said same face;
a second polymer layer having a first side that contacts an opposing second side of said first polymer layer; and
a metal plate contacting an opposing second side of said second polymer layer;
wherein said metal plate has one or more metal layers and is physically and electrically isolated from said bond pads of said semiconductor substrate.

2. The stress buffer structure of claim 1 wherein said metal plate includes a first metal layer disposed over said second side of said second polymer layer.

3. The stress buffer structure of claim 2 wherein said metal plate includes a second metal layer disposed over said first metal layer.

4. The stress buffer structure of claim 3 wherein said metal plate further includes a third metal layer disposed over said second metal layer.

5. The stress buffer structure of claim 2 wherein said first metal layer is selected from the group consisting of titanium, tungsten, vanadium and alloys or mixtures thereof.

6. The stress buffer structure of claim 3 wherein said second metal layer is selected from the group consisting of copper, aluminium, nickel, and alloys or mixtures thereof.

7. The stress buffer structure of claim 4 wherein said third metal layer is selected from the group consisting of titanium, tungsten, vanadium, and alloys or mixtures thereof.

8. The stress buffer structure of claim 5 wherein said first metal layer has a thickness of from about 0.02 to about 20 microns.

9. The stress buffer structure of claim 6 wherein said second metal layer has a thickness of from about 0.2 to about 20 microns.

10. The stress buffer structure of claim 7 wherein said third metal layer has a thickness of from about 0.02 to about 2 microns.

11. The stress buffer structure of claim 2 further comprising a third polymer layer overlaying and in contact with said metal plate.

12. The stress buffer structure of claim 1 wherein said first polymer layer is selected from the group consisting of polyimide, benzocyclobutene, benzocyclobutene-based polymers and polybenzoxazole.

13. The stress buffer structure of claim 1 wherein said second polymer layer is selected from the group consisting of polyimide, benzocyclobutene, benzocyclobutene-based polymers and polybenzoxazole.

14. The stress buffer structure of claim 11 wherein said third polymer layer is selected from the group consisting of polyimide, benzocyclobutene, benzocyclobutene-based polymers and polybenzoxazole.

15. The stress buffer structure of claim 12 wherein said first polymer layer has a thickness of from about 1 to about 50 microns.

16. The stress buffer structure of claim 13 wherein said second polymer layer has a thickness of from bout 1 to 50 microns.

17. The stress buffer structure of claim 14 wherein said third polymer layer has a thickness of from about 1 to 50 microns.

18. The stress buffer structure of claim 2 wherein said semiconductor substrate has at least one feature sensitive to stress, and wherein said first polymer layer covers at least one of said features.

19. The stress buffer structure of claim 2 wherein said second polymer layer overlays said first polymer layer and extends onto a portion of said passivation layer.

20. The stress buffer structure of claim 2 wherein said metal plate overlays said second polymer layer and extends onto a portion of said first polymer layer.

21. The stress buffer structure of claim 11 wherein said third polymer layer overlays said metal plate and extends onto at least a portion of said first polymer layer and said passivation layer.

22. The stress buffer structure of claim 11 wherein said third polymer layer overlays said metal plate and extends onto at least a portion of said second polymer layer.

23. The stress buffer structure of claim 22 wherein said third polymer layer further extends onto at least a portion of said passivation layer.

24. The stress buffer structure of claim 11 wherein said third polymer layer overlays said metal plate and extends onto at least a portion of said first, second polymer layers and said passivation layer.

25. A stress buffer structure intended to be disposed adjacent a face of a semiconductor substrate comprising:
a first polymer layer having at least a first side contacting at least part of a polymer coating formed on said semiconductor substrate, said semiconductor substrate having one or more bond pads on said same face; and
a metal plate contacting an opposing second side of said first polymer layer;
wherein said metal plate has one or more metal layers and is physically and electrically isolated from said bond pads of said semiconductor substrate.

26. The stress buffer structure of claim 25 wherein said metal plate includes a first metal layer disposed over said second side of said first polymer layer.

27. The stress buffer structure of claim 26 wherein said first metal layer has a thickness of from about 0.02 to about 20 microns, and is selected from the group consisting of titanium, tungsten, vanadium, and alloys or mixtures thereof.

28. The stress buffer structure of claim 26 wherein said metal plate includes a second metal layer disposed over said first metal layer, said second metal layer having a thickness of from about 0.2 to 20 microns, and is selected from the group consisting of copper, aluminium, nickel, and alloys or mixtures thereof.

29. The stress buffer structure of claim 28 wherein said metal plate includes a third metal layer on said second metal layer.

30. The stress buffer structure of claim 25 wherein said first polymer layer is selected from the group consisting of polyimide, benzocyclobutene, benzocyclobutene-based polymers and polybenzoxazole.

31. The stress buffer structure of claim 25 wherein said first polymer layer has a thickness of from about 1 to 50 microns.

32. The stress buffer structure of claim 25 wherein said semiconductor substrate has at least one feature sensitive to stress, and wherein said first polymer layer covers at least one of said features.

33. The stress buffer structure of claim 25 wherein said metal plate overlays said first polymer layer and extends onto a portion of said polymer coating.

34. The stress buffer structure of claim 25 further comprising a second polymer layer disposed over said metal plate.

35. The stress buffer structure of claim 34 wherein said second polymer layer overlays said metal plate and extends onto at least a portion of said first polymer layer.

36. The stress buffer structure of claim 34 wherein said second polymer layer overlays said metal plate and extends onto at least a portion of said first polymer layer and said polymer coating.

37. A semiconductor package comprising:
a semiconductor substrate having at least one bond pad and a passivation layer formed on a face of said substrate, said passivation layer having apertures that expose at least a portion of each said bond pad;
a stress buffer structure disposed adjacent said face of said semiconductor substrate, wherein said stress buffer structure comprises:
a first polymer layer having at least a first side contacting at least part of said passivation layer;
a second polymer layer having a first side that contacts an opposing second side of said first polymer layer; and
a metal plate contacting an opposing second side of said second polymer layer;
wherein said metal plate has one or more metal layers and is physically and electrically isolated from said bond pads of said semiconductor substrate.

38. The semiconductor package of claim 37, wherein said metal plate includes a first metal layer deposited on said second side of said second polymer layer, wherein said first metal layer has a thickness of from about 0.02 to 20 microns and is selected from the group consisting of titanium, tungsten, vanadium, and alloys or mixtures thereof.

39. The semiconductor package of claim 38 wherein said metal plate includes a second metal layer formed on said first metal layer; said second metal layer having a thickness of from about 0.2 to about 20 microns and being selected from the group consisting of copper, aluminium, nickel, and alloys or mixtures thereof.

40. The semiconductor package of claim 39 wherein said metal plate includes a third metal layer formed on said second metal layer, said third metal layer having a thickness of from about 0.02 to about 2 microns and being selected from the group consisting of titanium, tungsten, vanadium, and alloys or mixtures thereof.

41. The semiconductor package of claim 37 wherein each of said first and second polymer layer is selected from the group consisting of polyimide, benzocyclobutene, benzocyclobutene-based polymers and polybenzoxazole; and each of said first and second polymer has a thickness of from about 1 to 50 microns.

42. The semiconductor package of claim 37 further comprising a third polymer layer disposed over said metal plate.

43. The semiconductor package of claim 37 wherein said semiconductor substrate has at least one feature sensitive to stress, and wherein said first polymer layer covers at least one of said features.

44. A semiconductor package comprising:
a semiconductor substrate having at least one bond pad and a polymer coating formed on a face of said substrate, said polymer coating having a set of apertures that expose at least a portion of each said bond pad;
a stress buffer structure disposed on said polymer coating of said semiconductor substrate, wherein said stress buffer structure comprises:
a first polymer layer having at least a first side contacting at least part of said polymer coating layer; and
a metal plate contacting an opposing second side of said first polymer layer;
wherein said metal plate has one or more metal layers and is physically and electrically isolated from said bond pads of said semiconductor substrate.

45. The semiconductor package of claim 44 wherein said metal plate includes a first metal layer deposited on said second side of said first polymer layer, wherein said first metal layer is selected from the group consisting of titanium, tungsten, vanadium, and alloys or mixtures thereof.

46. The semiconductor package of claim 45 wherein said metal plate includes a second metal layer disposed over said first metal layer, said second metal layer being selected from the group consisting of copper, aluminum, nickel, and alloys or mixtures thereof.

47. The semiconductor package of claim 46 wherein said metal plate includes a third metal layer deposited on said second metal layer; said third metal layer being selected from titanium, tungsten, vanadium, and alloys or mixtures thereof.

48. The semiconductor package of claim 44 further comprising a second polymer layer disposed over said metal plate.

49. The semiconductor package of claim 48 wherein each of said first and second polymer layer is selected from the group consisting of polyimide, benzocyclobutene, benzocyclobutene-based polymers and polybenzoxazole; and each of said first and second polymer has a thickness of from about 1 to 50 microns.

50. A method for forming a semiconductor package comprising:
providing a substrate having at least one bond pad and a passivation layer formed thereon, said passivation layer including apertures that expose at least a portion of each said bond pad;
forming a stress buffer structure over said passivation layer, said stress buffer structure comprising:
a first polymer layer having at least a first side contacting at least part of said passivation layer;
a second polymer layer having a first side that contacts an opposing second side of said first polymer layer; and
a metal plate contacting an opposing second side of said second polymer layer;
wherein said metal plate has one or more metal layers and is physically and electrically isolated from said bond pads of said semiconductor substrate.

51. The method of claim 50 wherein said metal plate includes a first metal layer deposited on said second side of said second polymer layer; wherein said first metal layer is selected from the group consisting of titanium, tungsten, vanadium, and alloys or mixtures thereof; and wherein said first metal layer has a thickness of from about 0.02 to about 20 microns.

52. The method of claim 50 wherein each of said first and second polymer layer is selected from the group consisting of polyimide, benzocyclobutene, benzocyclobutene-based polymers and polybenzoxazole; and each of said first and second polymer has a thickness of from about 1 to 50 microns.

53. The method of claim 50 wherein said semiconductor substrate has at least one feature sensitive to stress, and wherein said first polymer layer covers at least one of said features.

54. A method for forming a semiconductor package comprising:
providing a substrate having at least one bond pad and a polymer coating formed thereon, said polymer coating including a set of apertures that expose at least a portion of each said bond pad;
forming a stress buffer structure over said polymer coating, said stress buffer structure comprising:
a first polymer layer having at least a first side contacting at least part of said polymer coating; and
a metal plate contacting an opposing second side of said first polymer layer;
wherein said metal plate has one or more metal layers and is physically and electrically isolated from said bond pads of said semiconductor substrate.
